(19) United States
(12) Patent Application Publication
(10) Pub. No.: US 2024/0113405 A1
(43) Pub. Date: Apr. 4, 2024

(54) PHASE SHIFTER AND PHASE SHIFTING METHOD THEREFOR

(71) Applicant: NEC Corporation, Minato-ku, Tokyo (JP)

(72) Inventors: Koya Takata, Tokyo (JP); Kenjl Wakafuji, Tokyo (JP); Fujio Okumura, Kanagawa (JP)

(73) Assignee: NEC Corporation, Minato-ku, Tokyo (JP)

(21) Appl. No.: 18/274,635

(22) PCT Filed: Feb. 3, 2022
(86) PCT No.: PCT/JP2022/004275

§ 371 Date: Jul. 27, 2023

(30) Foreign Application Priority Data
Mar. 29, 2021 (JP) 2021-056222

(51) Int. Cl. H01P 1/18; H01Q 3/36

(52) U.S. Cl. CPC H01P 1/18; H01Q 3/36

(57) ABSTRACT

A phase shifter includes: transmission channels that have one ends connected to an antenna element, are formed with a gap, and have different lengths; movable electrodes that are provided to the gaps, and move in a direction parallel to the transmission channels to be switched to an on-state in which the movable electrode overlaps transmission channel end portions on both ends of a corresponding one of the gaps and is inductively coupled with the transmission channel end portions and to an off-state in which the movable electrode does not overlap at least one of the transmission channel end portions on both ends of the corresponding gap and is not inductively coupled with the at least one of the transmission channel end portions; and MEMS mechanisms that change a phase difference by switching the movable electrodes to one of the on-state and the off-state to switch lengths of the transmission channels.

### TECHNICAL FIELD

The present invention relates to a phase shifter for an antenna and a phase shifting method for the phase shifter.

### BACKGROUND ART

A phase shifter that controls a phase with liquid crystal is known (e.g., see Patent Literature 1).

### CITATION LIST

### Patent Literature

[Patent Literature 1] Published Japanese Translation of PCT International Publication for Patent Application, No. 2014-531843

### SUMMARY OF INVENTION

### Technical Problem

The phase shifter described above may decrease a responsivity of an antenna because an operation speed of the liquid crystal is low.

An objective of the present disclosure is to provide a phase shifter and a phase shifting method for the phase shifter to solve the problem.

### Solution to Problem

An aspect for achieving the objective is a phase shifter including:

a plurality of transmission channels that have one ends connected to an antenna element, and each of which is formed with a gap, the transmission channels having different lengths;

a plurality of movable electrodes that are provided to the gaps of the transmission channels, and each of which moves in a direction parallel to the transmission channels to be switched to an on-state and moves in a direction parallel to the transmission channels to be switched to an off-state, the on-state being a state in which the movable electrode overlaps transmission channel end portions on both ends of a corresponding one of the gaps and is inductively coupled with the transmission channel end portions, the off-state being a state in which the movable electrode does not overlap at least one of the transmission channel end portions on both ends of the corresponding gap and is not inductively coupled with the at least one of the transmission channel end portions; and

a plurality of MEMS mechanisms that move the movable electrodes,

in which the MEMS mechanisms change a phase difference by switching the movable electrodes to one of the on-state and the off-state to switch lengths of the transmission channels.

An aspect for achieving the objective may be a phase shifter including:

a pair of fixed electrodes that are provided to transmission channel end portions on both ends of a gap formed in a transmission channel connected to an antenna element;

a movable electrode that moves in at least one of a parallel direction and a perpendicular direction while both ends of the movable electrode overlap and are inductively coupled with both of the pair of fixed electrodes, the parallel direction being a direction parallel to the fixed electrodes, the perpendicular direction being a direction perpendicular to the fixed electrodes; and

a MEMS mechanism that moves the movable electrode,

in which the MEMS mechanism changes a phase difference by at least one of causing the movable electrode to move in the parallel direction to change an amount of overlap between both ends of the movable electrode and the pair of fixed electrodes and causing the movable electrode to move in the perpendicular direction to change a distance between both ends of the movable electrode and the pair of fixed electrodes.

An aspect for achieving the objective may be a phase shifter including:

a plurality of transmission channels that have one ends connected to an antenna element, and each of which is formed with a gap, the transmission channels having different lengths;

a plurality of first movable electrodes that are provided to the gaps of the transmission channels, and each of which moves in a direction parallel to the transmission channels to be switched to an on-state and moves in a direction parallel to the transmission channels to be switched to an off-state, the on-state being a state in which the first movable electrode overlaps transmission channel end portions on both ends of a corresponding one of the gaps and is inductively coupled with the transmission channel end portions, the off-state being a state in which the first movable electrode does not overlap at least one of the transmission channel end portions on both ends of the corresponding gap and is not inductively coupled with the at least one of the transmission channel end portions;

pairs of fixed electrodes that are provided to both ends of the gaps of the transmission channels;

second movable electrodes each of which moves in at least one of a parallel direction and a perpendicular direction while both ends of the second movable electrode overlap and are inductively coupled with both of a corresponding one of the pairs of fixed electrodes, the parallel direction being a direction parallel to the fixed electrodes, the perpendicular direction being a direction perpendicular to the corresponding fixed electrodes; and

a plurality of MEMS mechanisms that move the first and second movable electrodes,

in which the MEMS mechanisms change a phase difference by at least one of switching each of the first movable electrodes to one of the on-state and the off-state to switch the lengths of the transmission channels and changing at least one of an amount of overlap and a distance between both ends of each second movable electrode and a corresponding one of the pairs of fixed electrodes to change a coupling capacitance of the second movable electrode and the corresponding fixed electrodes.

An aspect for achieving the objective may be a phase shifting method for a phase shifter that includes:

a plurality of transmission channels that have one ends connected to an antenna element, and each of which is formed with a gap, the transmission channels having different lengths;

a plurality of movable electrodes that are provided to the gaps of the transmission channels, and each of which moves in a direction parallel to the transmission channels to be switched to an on-state and moves in a direction parallel to the transmission channels to be switched to an off-state, the on-state being a state in which the movable electrode overlaps transmission channel end portions on both ends of a corresponding one of the gaps and is inductively coupled with the transmission channel end portions, the off-state being a state in which the movable electrode does not overlap at least one of the transmission channel end portions on both ends of the corresponding gap and is not inductively coupled with the at least one of the transmission channel end portions; and

a plurality of MEMS mechanisms that move the movable electrodes,

in which the MEMS mechanisms change a phase difference by switching the movable electrodes to one of the on-state and the off-state to switch lengths of the transmission channels.

An aspect for achieving the objective may be a phase shifting method for a phase shifter that includes:

a pair of fixed electrodes that are provided to transmission channel end portions on both ends of a gap formed in a transmission channel connected to an antenna element;

a movable electrode that moves in at least one of a parallel direction and a perpendicular direction while both ends of the movable electrode overlap and are inductively coupled with both of the pair of fixed electrodes, the parallel direction being a direction parallel to the fixed electrodes, the perpendicular direction being a direction perpendicular to the fixed electrodes; and

a MEMS mechanism that moves the movable electrode,

in which the MEMS mechanism changes a phase difference by at least one of causing the movable electrode to move in the parallel direction to change an amount of overlap between both ends of the movable electrode and the pair of fixed electrodes and causing the movable electrode to move in the perpendicular direction to change a distance between both ends of the movable electrode and the pair of fixed electrodes.

An aspect for achieving the objective may be a phase shifting method for a phase shifter that includes:

a plurality of transmission channels that have one ends connected to an antenna element, and each of which is formed with a gap, the transmission channels having different lengths;

a plurality of first movable electrodes that are provided to the gaps of the transmission channels, and each of which moves in a direction parallel to the transmission channels to be switched to an on-state and moves in a direction parallel to the transmission channels to be switched to an off-state, the on-state being a state in which the first movable electrode overlaps transmission channel end portions on both ends of a corresponding one of the gaps and is inductively coupled with the transmission channel end portions, the off-state being a state in which the first movable electrode does not overlap at least one of the transmission channel end portions on both ends of the corresponding gap and is not inductively coupled with the at least one of the transmission channel end portions;

pairs of fixed electrodes that are provided to transmission channel end portions on both ends of the gaps;

second movable electrodes each of which moves in at least one of a parallel direction and a perpendicular direction while both ends of the second movable electrode overlap and are inductively coupled with both of a corresponding one of the pairs of fixed electrodes, the parallel direction being a direction parallel to the fixed electrodes, the perpendicular direction being a direction perpendicular to the corresponding fixed electrodes; and

a plurality of MEMS mechanisms that move the first and second movable electrodes,

in which the MEMS mechanisms change a phase difference by at least one of switching each of the first movable electrodes to one of the on-state and the off-state to switch the lengths of the transmission channels and changing at least one of an amount of an overlapping portion and a distance between both ends of each second movable electrode and a corresponding one of the pairs of fixed electrodes to change a coupling capacitance of the second movable electrode and the corresponding fixed electrodes.

### Advantageous Effects of Invention

According to the present disclosure, a phase shifter and a phase shifting method for the phase shifter to solve the problem can be provided.

### BRIEF DESCRIPTION OF DRAWINGS

FIG. 1 is a diagram illustrating a schematic configuration of a phase shifter according to the present example embodiment;

FIG. 2 is a diagram schematically illustrating an operation of a movable electrode according to the present example embodiment;

FIG. 3 is a block diagram illustrating a schematic configuration of a phase shifter according to the present example embodiment;

FIG. 4 is a diagram schematically illustrating an operation of a movable electrode according to the present example embodiment; and

FIG. 5 is a diagram illustrating a schematic configuration of a phase shifter according to the present example embodiment.

### EXAMPLE EMBODIMENT

### First Example Embodiment

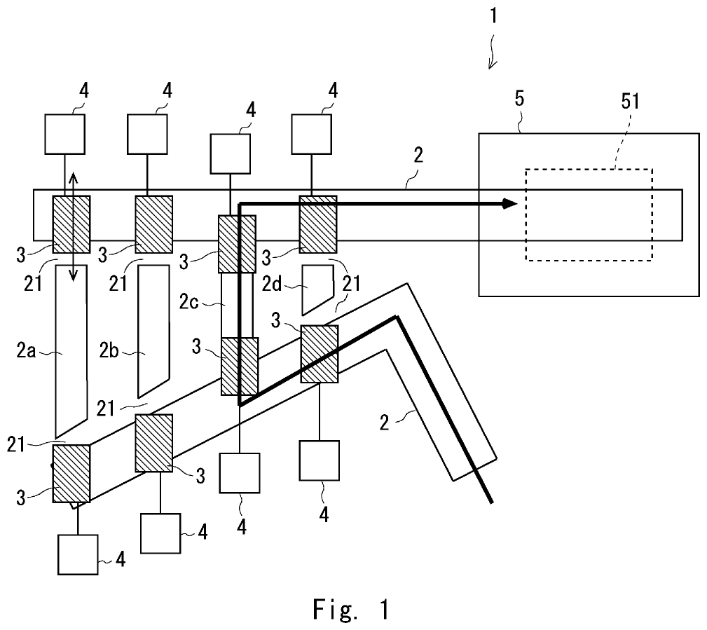

Example embodiments of the present invention will be described below with reference to the drawings. FIG. 1 is a diagram illustrating a schematic configuration of a phase shifter according to the present example embodiment. A phase shifter 1 according to the present example embodiment includes a plurality of transmission channels 2 having different lengths, a plurality of movable electrodes 3 provided in each of the transmission channels 2, and a plurality of MEMS mechanisms 4 provided to the movable electrodes 3.

To one ends of the transmission channels 2, an antenna element 5 is connected. The antenna element 5 is, for example, a patch antenna or the like and is formed with a signal supply window 51 or the like.

Each transmission channel 2 is provided with gaps 21 having a certain space. In FIG. 1, from left to right, for example, a first transmission channel 2a, a second transmission channel 2b, a third transmission channel 2c, and a fourth transmission channel 2d are provided and have lengths that are set in an ascending order being this order. The transmission channels 2 are each formed of, for example, a conductive metal member such as copper.

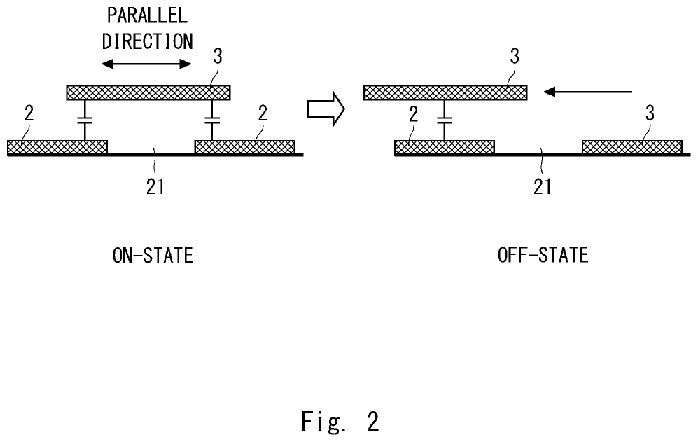

The gaps 21 of each transmission channel 2 are provided with the movable electrode 3 that are movable in directions parallel to the transmission channel 2. The movable electrodes 3 are each formed of, for example, a conductive metal member such as copper. FIG. 2 is a diagram schematically illustrating an operation of a movable electrode according to the present example embodiment. The movable electrode 3 moves in the parallel directions in a contactless manner while keeping a certain distance with the transmission channel 2.

The movable electrode 3 moves in a direction parallel to the transmission channels 2 and overlaps transmission channel end portions on both ends of the gap 21, thus coming into an on-state (the left side of FIG. 2) in which the movable electrode 3 is inductively coupled with the transmission channel end portions. When the movable electrode 3 comes into the on-state, the transmission channel end portions on both ends of the gap 21 and both ends of the movable electrode 3 are capacitively coupled to be electrified.

The movable electrode 3 moves in a direction parallel to the transmission channels 2 not to overlap at least one of the transmission channel end portions on both ends of the gap 21, thus coming into an off-state (the right side of FIG. 2) in which the movable electrode 3 is not inductively coupled with the at least one of the transmission channel end portions. When the movable electrode 3 comes into the off-state, the at least one of the transmission channel end portions on both ends of the gap 21 and one of both ends of the movable electrode 3 is not capacitively coupled, not to be electrified. As seen from the above, the movable electrode 3 has a switching function of switching between the on-state and the off-state by moving in the parallel directions.

The MEMS mechanisms 4 are provided to the movable electrodes 3 and move the movable electrodes 3 in the parallel directions. The MEMS mechanisms 4 are connected to the movable electrodes 3 with insulators interposed therebetween. The MEMS (Micro Electro Mechanical Systems) mechanisms are each a device with a micron-level structure in which a sensor and an actuator being mechanical element components, an electronic circuit, and the like are collectively placed on a semiconductor silicon substrate, a semiconductor glass substrate, a semiconductor organic material, or the like. The MEMS mechanisms 4 have the feature of being capable of causing the movable electrodes 3 to move fast and minutely.

The MEMS mechanisms 4 switch the movable electrodes 3 to the on-state or the off-state to switch the lengths of the transmission channels 2, thus changing a phase difference. Here, an example of a phase shifting method by the phase shifter 1 will be described specifically.

For example, as illustrated in FIG. 1, the MEMS mechanisms 4 switch the movable electrodes 3 over the gaps 21 of the third transmission channel 2c, which is the third longest, to the on-state while switching the movable electrodes 3 over the gaps 21 of the other transmission channels, the first, second, and fourth transmission channels 2a, 2b, and 2d, to the off-state. The MEMS mechanisms 4 switches the movable electrodes 3 over the gaps 21 of the first transmission channel 2a, which is the longest, to the on-state while switching the movable electrodes 3 over the gaps 21 of the other transmission channels, the second to fourth transmission channels 2b, 2c, and 2d to the off-state.

Likewise, the MEMS mechanisms 4 switches the movable electrodes 3 over the gaps 21 of a transmission channel 2 having a specific length to the on-state while switching the movable electrodes 3 over the gaps 21 of the other transmission channels 2 to the off-state. In this manner, the phase difference can be changed freely by changing a length of a path of the transmission channel 2 through which a signal passes.

Note that the number of the transmission channels 2, positions of the gaps 21, and shapes of the transmission channels 2 illustrated in FIG. 1 constitute an example and are not limiting. The number of the transmission channels 2, the positions of the gaps 21, and the shapes of the transmission channels 2 may be any number, any positions, and any shapes, respectively, as long as the lengths of the transmission channels 2 can be switched by switching the movable electrodes 3 over the gaps 21 to the on-state or the off-state.

The phase shifter in related art raises a problem of a decrease in responsivity of an antenna because an operation speed of liquid crystal is low.

In contrast, in the phase shifter 1 according to the present example embodiment, as described above, the MEMS mechanisms 4 switch the movable electrodes 3 to the on-state or the off-state to switch the lengths of the transmission channels 2, thus changing a phase difference. This makes it possible, with the high-speed operation feature of the MEMS mechanisms 4, to switch the movable electrodes 3 to the on-state or the off-state at high speed, thus changing the phase difference at high speed, so that a responsivity of an antenna can be made high. For example, while a response speed of a liquid crystal type antenna is about several milliseconds to several tens of milliseconds, a response speed of the phase shifter according to the present example embodiment is about 10 μs to 100 μs, which is highly fast.

In addition, the MEMS mechanisms 4 uses electrostatic force and are thus unlikely to be influenced by temperature fluctuations compared with liquid crystal, therefore being excellent in controllability. For this reason, it is possible to control the phase difference with higher accuracy. In addition, the MEMS mechanisms 4 can be formed over a large area, and thus an antenna having a desired size can be produced inexpensively. Further, because lines are made thinner with an increase in frequency, use of the MEMS mechanisms 4 according to the present example embodiment, which are minute, is advantageous.

Note that dielectrics may be placed among the movable electrodes 3 and the transmission channel end portions on both ends of the gaps 21. This produces a wavelength shortening effect, enabling the phase shifter 1 to be further reduced in size.

### Second Example Embodiment

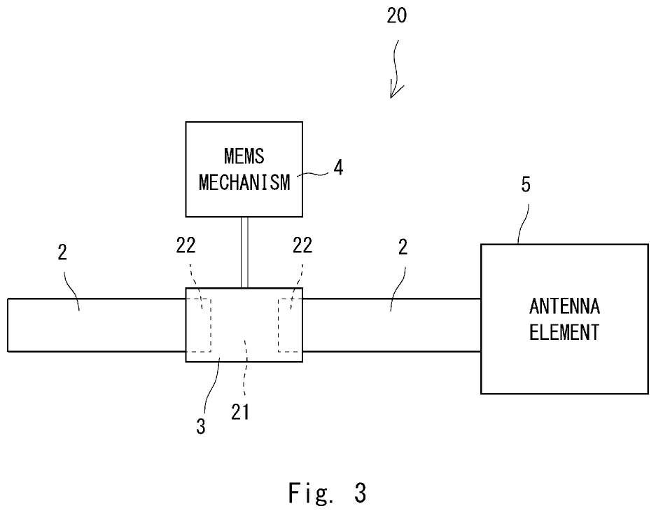

FIG. 3 is a block diagram illustrating a schematic configuration of a phase shifter according to the present example embodiment. A phase shifter 20 according to the present example embodiment includes a pair of fixed electrodes 22, a movable electrode 3 provided to the pair of fixed electrodes 22, and a MEMS mechanism 4 provided to the movable electrode 3.

The pair of fixed electrodes 22 are provided at transmission channel end portions on both ends of a gap 21 formed in a transmission channel 2. The fixed electrodes 22 are each formed of, for example, a conductive metal member such as copper. The movable electrode 3 is provided extending over the gap 21 of the transmission channel 2. The pair of fixed electrodes 22 and the transmission channel end portions on both ends of the gap 21 may be integrally formed. To one ends of the transmission channels 2, an antenna element 5 is connected.

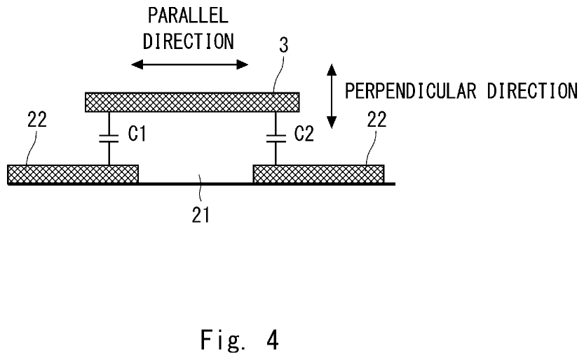

FIG. 4 is a diagram schematically illustrating an operation of a movable electrode according to the present example embodiment. The pair of fixed electrodes 22 are disposed a certain distance away from each other. The movable electrode 3 moves in directions parallel to the fixed electrodes 22 in a contactless manner while keeping a certain distance with the fixed electrodes 22.

The pair of fixed electrodes 22 overlap and are inductively coupled with both ends of the movable electrode 3. For example, as illustrated in FIG. 4, a coupling capacitance of the fixed electrode 22 on the left side and a left end of the movable electrode 3 is Cl, and a coupling capacitance of the fixed electrode 22 on the right side and a right end of the movable electrode 3 is C2. When both ends of the movable electrode 3 move in the parallel directions while overlapping and being inductively coupled with the pair of fixed electrodes 22, a series coupling capacitance of C1 and C2 changes.

The MEMS mechanism 4 causes the movable electrode 3 to move in the parallel directions, thus changing an amount of overlap between both ends of the movable electrode 3 and the pair of fixed electrodes 22. This can change the coupling capacitances between the movable electrode 3 and the fixed electrodes 22, thus changing a phase difference. Note that the MEMS mechanism 4 is formed at a position at which the MEMS mechanism 4 does not influence signals.

FIG. 3 illustrates a configuration in which the transmission channel 2 is provided with one movable electrode 3, one gap 21, and one MEMS mechanism 4, but the configuration is not limiting. The transmission channel 2 may be provided with any number of movable electrodes 3, any number of gaps 21, and any number of MEMS mechanisms 4.

In the phase shifter 1 according to the present example embodiment, as described above, the MEMS mechanism 4 causes the movable electrode 3 to move in the parallel directions, changing the amount of overlap between the movable electrode 3 and the fixed electrodes 22. This makes it possible, with the high-speed operation feature of the MEMS mechanisms 4, to change the amount of overlap between the movable electrodes 3 and the fixed electrodes 22 at high speed, thus changing the phase difference at high speed, so that a responsivity of an antenna can be made high.

In addition, the MEMS mechanism 4 changes the amount of overlap between both ends of the movable electrode 3 and the pair of fixed electrodes 22, thus enabling the coupling capacitance of the movable electrode 3 and the fixed electrodes 22 to be continuously changed. This enables a fine adjustment of the phase difference in accordance with the amount of overlap, and a fine tuning of the phase difference can be performed at high speed.

Note that the MEMS mechanism 4 may cause the movable electrode 3 to move in perpendicular directions to change a distance between both ends of the movable electrode 3 and the pair of fixed electrodes 22, thus changing the coupling capacitance of the movable electrode 3 and the fixed electrodes 22 to change the phase difference. Note that the MEMS mechanism 4 more preferably causes the movable electrode 3 to move in the parallel directions as described above because the capacitive coupling can be kept strong.

Further, the MEMS mechanism 4 may cause the movable electrode 3 to move in the perpendicular directions to change the distance between both ends of the movable electrode 3 and the pair of fixed electrodes 22 while causing the movable electrode 3 to move in the parallel directions to change the amount of overlap between both ends of the movable electrode 3 and the pair of fixed electrodes 22, thus changing the phase difference.

### Third Example Embodiment

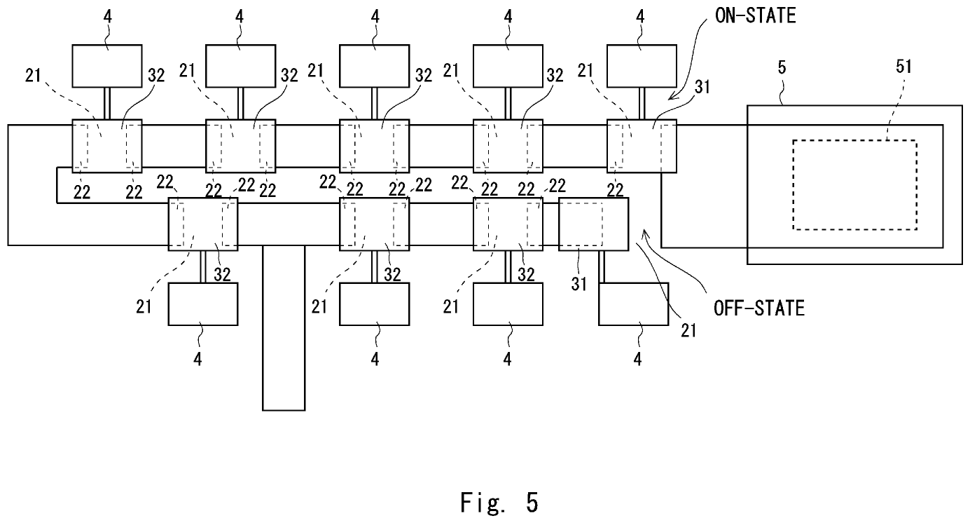

FIG. 5 is a diagram illustrating a schematic configuration of a phase shifter according to the present example embodiment. A phase shifter 30 according to the present example embodiment includes a plurality of transmission channels 2 having different lengths, a plurality of first and second movable electrodes 31 and 32 provided in each of the transmission channels 2, and a plurality of MEMS mechanisms 4 provided to the first and second movable electrodes 31 and 32.

To one ends of the transmission channels 2, an antenna element 5 is connected. In each transmission channel 2, a plurality of gaps 21 are formed. Note that transmission channel end portions at both ends of each of the gaps 21 may be provided with fixed electrodes 22. The first movable electrodes 31 are provided to gaps 21 of the transmission channels 2, move in a direction parallel to the transmission channels 2 and overlap transmission channel end portions on both ends of the gaps 21, thus coming into an on-state in which the first movable electrodes 31 are inductively coupled with the transmission channel end portions.

Each of the first movable electrodes 31 moves in the direction parallel to the transmission channels 2 not to overlap at least one of the transmission channel end portions on both ends of the gap 21, thus coming into an off-state in which the first movable electrode 31 is not inductively coupled with the at least one of the transmission channel end portions. The first movable electrodes 31 have a switching function of switching between the on-state and the off-state by moving in the parallel directions.

Transmission channel end portions at both ends of each of the gaps 21 are provided with a pair of fixed electrodes 22. The fixed electrodes 22 may be integrally formed with the transmission channel end portions on both ends of the gap 21. Each of the second movable electrode 32 moves in directions parallel to the pair of fixed electrodes 22 while both ends of the second movable electrode 32 overlap and are inductively coupled with both fixed electrodes 22.

Note that each of the second movable electrode 32 may move in directions perpendicular to the pair of fixed electrodes 22 while both ends of the second movable electrode 32 overlap and are inductively coupled with both fixed electrodes 22. The MEMS mechanisms 4 cause the first and second movable electrodes 31 and 32 to move.

The MEMS mechanisms 4 switch the first movable electrodes 31 to the on-state or the off-state to switch the lengths of the transmission channels 2. This enables a stepwise adjustment of a phase difference in accordance with the lengths of the transmission channels 2 that are preset, and the phase difference can be widely modulated.

Further, the MEMS mechanisms 4 each change an amount of overlap between both ends of the second movable electrode 32 and the pair of fixed electrodes 22, thus changing a coupling capacitance of the second movable electrode 32 and the fixed electrodes 22. This enables a fine adjustment of the phase difference in accordance with the amount of overlap, and a fine tuning of the phase difference can be performed.

That is, by switching the first movable electrodes 31 to the on-state or the off-state, a length of a path of the transmission channel 2 through which a signal passes is changed, so that the phase difference can be roughly adjusted. Further, by adjusting the amount of overlap of each second movable electrode 32 to change the coupling capacitance of the second movable electrode 32 and the fixed electrodes 22, a fine tuning of the phase difference can be performed. This enables easy and high-accuracy adjustment of the phase difference.

Note that the number of the transmission channels 2, the numbers and positions of the first and second movable electrodes 31 and 32, positions of the gaps 21, and shapes of the transmission channels 2 illustrated in FIG. 5 constitute an example and are not limiting. The number of the transmission channels 2, the positions of the gaps 21, and the shapes of the transmission channels 2 may be any number, any positions, and any shapes, respectively, as long as the lengths of the transmission channels 2 can be switched by switching the first movable electrodes 31 to the on-state or the off-state.

In addition, the number and positions of the second movable electrodes 32 may be any number and shapes, respectively, as long as the fine tuning of the phase difference can be performed. For example, a single or a plurality of gaps 21 may be newly formed in the transmission channels 2 illustrated in FIG. 1, and the gaps 21 may be provided with second movable electrodes 32.

Certain example embodiments of the present invention have been described. However, these example embodiments are presented by way of example only, and are not intended to limit the scope of the invention. These novel example embodiments may be carried out in other various forms. Various omissions, substitutions, and changes may be made without departing from the gist of the invention. These example embodiments and modifications thereof shall be within the scope and the gist of the invention and within the scope of the inventions described in claims and the scope of equivalents of the claims.

This application is based upon and claims the benefit of priority from Japanese Patent Application No. 2021-056222, filed on Mar. 29, 2021, the disclosure of which is incorporated herein in its entirety by reference.

### REFERENCE SIGNS LIST

1 PHASE SHIFTER
2 TRANSMISSION CHANNEL
3 MOVABLE ELECTRODE
4 MEMS MECHANISM
5 ANTENNA ELEMENT
20 PHASE SHIFTER
21 GAP
22 FIXED ELECTRODE
30 PHASE SHIFTER
31 FIRST MOVABLE ELECTRODE
32 SECOND MOVABLE ELECTRODE
51 SIGNAL SUPPLY WINDOW

What is claimed is:

1. A phase shifter comprising:
a plurality of transmission channels that have one ends connected to an antenna element, and each of which is formed with a gap, the transmission channels having different lengths;
a plurality of movable electrodes that are provided to the gaps of the transmission channels, and each of which moves in a direction parallel to the transmission channels to be switched to an on-state and moves in a direction parallel to the transmission channels to be switched to an off-state, the on-state being a state in which the movable electrode overlaps transmission channel end portions on both ends of a corresponding one of the gaps and is inductively coupled with the transmission channel end portions, the off-state being a state in which the movable electrode does not overlap at least one of the transmission channel end portions on both ends of the corresponding gap and is not inductively coupled with the at least one of the transmission channel end portions; and
a plurality of MEMS mechanisms that move the movable electrodes,
wherein the MEMS mechanisms change a phase difference by switching the movable electrodes to one of the on-state and the off-state to switch lengths of the transmission channels.

2. (canceled)

3. A phase shifter comprising:
a plurality of transmission channels that have one ends connected to an antenna element, and each of which is formed with a gap, the transmission channels having different lengths;
a plurality of first movable electrodes that are provided to the gaps of the transmission channels, and each of which moves in a direction parallel to the transmission channels to be switched to an on-state and moves in a direction parallel to the transmission channels to be switched to an off-state, the on-state being a state in which the first movable electrode overlaps transmission channel end portions on both ends of a corresponding one of the gaps and is inductively coupled with the transmission channel end portions, the off-state being a state in which the first movable electrode does not overlap at least one of the transmission channel end portions on both ends of the corresponding gap and is not inductively coupled with the at least one of the transmission channel end portions;
pairs of fixed electrodes that are provided to both ends of the gaps of the transmission channels;
second movable electrodes each of which moves in at least one of a parallel direction and a perpendicular direction while both ends of the second movable electrode overlap and are inductively coupled with both of a corresponding one of the pairs of fixed electrodes, the parallel direction being a direction parallel to the fixed electrodes, the perpendicular direction being a direction perpendicular to the corresponding fixed electrodes; and
a plurality of MEMS mechanisms that move the first and second movable electrodes,
wherein the MEMS mechanisms change a phase difference by at least one of switching each of the first movable electrodes to one of the on-state and the off-state to switch the lengths of the transmission channels and changing at least one of an amount of overlap and a distance between both ends of each second movable electrode and a corresponding one of the pairs of fixed electrodes to change a coupling capacitance of the second movable electrode and the corresponding fixed electrodes.

4. A phase shifting method for a phase shifter that includes:
a plurality of transmission channels that have one ends connected to an antenna element, and each of which is formed with a gap, the transmission channels having different lengths;
a plurality of movable electrodes that are provided to the gaps of the transmission channels, and each of which moves in a direction parallel to the transmission channels to be switched to an on-state and moves in a direction parallel to the transmission channels to be switched to an off-state, the on-state being a state in which the movable electrode overlaps transmission channel end portions on both ends of a corresponding one of the gaps and is inductively coupled with the transmission channel end portions, the off-state being a state in which the movable electrode does not overlap at least one of the transmission channel end portions on both ends of the corresponding gap and is not inductively coupled with the at least one of the transmission channel end portions; and
a plurality of MEMS mechanisms that move the movable electrodes,
wherein the MEMS mechanisms change a phase difference by switching the movable electrodes to one of the on-state and the off-state to switch lengths of the transmission channels.

5. (canceled)

6. (canceled)
